(19) United States
(12) Patent Application Publication
(10) Pub. No.: US 2006/0017055 A1
(43) Pub. Date: Jan. 26, 2006

(54) Method for manufacturing a display device with low temperature diamond coatings

(75) Inventors: Andre D. Cropper, Rochester, NY (US); Liya Regel, Potsdam, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 10/897,603

(22) Filed: Jul. 23, 2004

(51) Int. Cl. H01L 21/00; H01L 33/00

(52) U.S. Cl. 257/77; 438/105; 257/103; 438/22

(57) ABSTRACT

A display device with multiple low temperature diamond coatings, including a substrate as a base; an anode layer residing on the diamond substrate for emitting holes; a hole drift layer that includes a doped diamond coating residing on the anode layer; an emissive layer for emitting light and residing on the hole drift layer. The display device also includes an electron transport layer that includes a doped diamond coating residing on the light emitting layer; a cathode layer, residing on the electron transport layer, for emitting electrons that will drift towards the light emitting layer; and a diamond coated encapsulation layer for sealing the display device from atmospheric moisture; wherein the multiple low temperature diamond coatings are all formed below 750° C. on the display device.

### FIELD OF THE INVENTION

The present invention relates to a display device with multiple diamond coatings deposited by a chemical vapor transport process at temperatures below 750° C. and a method for the manufacture of such a display. This present invention can be used for Organic Light Emitting Diodes (OLED), back lights for Liquid Crystal Displays (LCD), flat light sources, flat panel displays (FPD), etc.

### BACKGROUND OF THE INVENTION

Organic light emitting devices (OLEDs) have been known for approximately two decades. All OLEDs work on the same general principles. One or more layers of a semiconducting organic or polymer material is used to form a light-emitting layer, which is sandwiched between two electrodes and formed on a substrate such as soda-lime glass or silicon. Once an electric field or potential difference is applied across the device, electrons, which are negatively charged, move from the cathode into the organic layer (s). At the same time the positively charged holes move from the anode into the organic layer (s) where they meet with the electrons, combine, and produce photons (light). Depending on the electronic makeup of the organic material, the emitted wavelength (color) of the light can be varied. Additionally, by controlling the selection of the organic material in addition to the dopants within the structure, or by other techniques known in the art, precise colors of light can be emitted by the OLED. Emitting red, blue, and green light simultaneously can form white light.

In a typical OLED, the light-emitting layer may be selected from any of a multitude of fluorescent organic crystalline or polymeric solids. The light-emitting layer may consist of a single layer, a single blended layer or multiple sublayers blended together. Either the anode or the cathode must be transparent in order to allow the emitted light to pass out of the device. The cathode is typically constructed of a low work-function material that allows electrons to be ejected. The anode is typically constructed of a high work-function material that allows holes to be injected into the organic or polymer materials via transport layers.

The properties of diamond are well known in the industry. It has excellent resistance to high temperature, a large bandgap (5.45 ev), high carrier mobilities (electron mobility of 2200 cm²/Vs and hole mobility of 1600 cm²/Vs), and a low dielectric constant of 5.5 to 5.7, which leads to a small dielectric loss. It is the hardest of all known materials (12000-15000 Kg/mm²); it has unsurpassed corrosion and erosion resistance; it has an electrical resistivity of 1013 to 10¹⁶ Ω-cm; and it has the highest elastic modulus, lowest compressibility, and highest thermal conductivity at 300 K (20 W/cm·K) of all known materials. It has the highest acoustic velocity, excellent optical transparency from infrared to ultraviolet (Transmittance from 0.22-2.5 to >6 μm) and a refractive index of 2.41.

As a semiconductor, diamond has a saturation velocity much greater than do Si, GaAs and InP (2.7×10⁷ cm/s for electrons and 1.0×10⁷ cm/s for holes), and an unusually high breakdown voltage (10⁷ V/cm). Diamond has also been estimated to be able to switch 100 kW of power at MHz frequencies. When hydrogenated, diamond has a negative electron affinity on the [111] surface enabling electron emission at low voltages without high vacuum and without degradation. Because of these characteristics, diamond is considered to be an excellent material for use in electronic devices and sensors that require high temperature tolerances, high frequencies, high electric fields, and radiation.

Studies have been conducted on diamond for applications in photosensors and light-emitting elements in the ultraviolet region based on its large bandgap, in heat sinks based on its high thermal conductivity and low specific heat, in surface acoustic wave devices based on its extremely high hardness, and in X-ray windows and optical materials based on its high transmittance and high refractive index.

To fully exploit all of the characteristics of diamond in various applications, it is necessary to first synthesize high quality single crystal diamond with low structural defects. At the present time single crystal diamond is mostly obtained by natural mining or synthesis under high pressure and high temperature. However, these diamond samples only have a limited crystal surface area on the order of 1-2 cm² at the largest and are very expensive to produce. Thus its applications are very limited.

Recently, Kobashi et al. in U.S. Pat. No. 6,198,218 issued in 2001 and Moyer et al. in U.S. Pat. No. 5,334,855 issued in 1994 made great strides in creating a one directional OLED device. Kobashi et al.'s device, as shown in FIG. 1, which improved on Moyer et al's semiconductor/phosphor polycrystalline LED and display device, uses diamond deposited at high temperatures (over 800° C.) by chemical vapor deposition (CVD) and doped with boron to form the hole drift layer (3) on top of the hole injection electrode (2), which sits on top of the substrate (9). The organic light-emitting layer (4) resides on top of the hole drift layer (3). On top of the organic light-emitting layer (4) are the electron drift layer (5) and the electron injection layer (6). The device is completed with a transparent layer (8) on top of the electron injection layer (6) and the emitted light (7) is through the transparent layer (8). The OLED device structure is completed with a transparent layer that allows light to be emitted. Kobashi et al. indicated that the optimum doping concentration of the diamond layer is 1.0×10¹⁹ to 1.0×10²¹/cm³. Kobashi et al. addressed some of the more common problems with OLED display devices and improved on the prior art by optimizing the doping of the boron in the diamond hole drift layer to increase long term operating stability by reducing thermal deterioration of the hole drift layer of the OLED display device and thus increase reliability. This improvement was possible because the diamond drift layer was more resistance to high temperatures and because diamond's increased hole mobility improved the light conversion efficiency.

However, both prior arts used methods to create the boron doped polycrystalline diamond (Moyer) and diamond-like carbon (Kobashi) layers at temperatures above 800° C. and only addressed optimizing the hole side of the OLED display device structure. Thus in the two step method disclosed by Kobashi et al., only the hole drift layer was created from a diamond film and thus the light conversion efficiency is increased only slightly because only the hole side of the device is improved. Also, the long term stability problem still occurs because the organic layer may undergo re-crystallization, form metal oxide impurities at the metal-organic interface, and other structural change that adversely affect the emissive properties of the device, due to exposure to oxygen or moisture. In addition, because a high temperature CVD process (above 800° C.) was used to form the diamond layer, manufacturing all layers for this device in a single continuous process within the chamber requires the device, including the light emissive layer, to be able to withstand the high temperatures that are present within CVD processing. However, the organic materials typically used to make OLED display devices are intolerant to temperatures above 200° C. Otherwise a multi-chambered, multi-step process facility would have to be used in which, the diamond drift layer would be created in one apparatus and then transferred to another apparatus to create the OLED display device. Also since only the cathode is transparent, a bi-directional OLED display device cannot be made from this structure.

Another approach aimed at improving the long-term stability of OLED devices was taken by Jones in U.S. Pat. No. 6,337,492 issued in 2002 and U.S. Pat. No. 5,920,080 issued in 1999. Jones used diamond-like amorphous carbon (DLC) material as a barrier layer and to function as an electron-hole injector for the device. The DLC acted as a barrier to moisture transport within the device and as a heat sink for heat generated during light emission. The DLC layer was deposited by laser ablation from graphite or plasma enhanced chemical vapor deposition (PECVD) and doped with lithium for use as an electron injector and with palladium for use as a hole injector. However, since the electron and hole mobilities of DLC films are much smaller than those of single crystal or polycrystalline diamond, the light conversion efficiency would be much less than a device made from diamond. In addition, since either the cathode or anode can be transparent in Jones' patent, a bi-directional OLED display device cannot be made from this structure. Also, since the thermal conductivity, chemical stability, and impermeability of DLC are greatly inferior to those of diamond such a device would become more susceptible to thermal and moisture damage than a device made from diamond.

There remains a need for a low temperature deposition process of a bi-directional device having high light conversion efficiencies and long-term stability and reliability in a continuous manufacturing process. None of the above-described processes have sufficiently met this specific need.

### SUMMARY OF THE INVENTION

The aforementioned need is addressed according to the present invention by providing a display device with multiple low temperature diamond coatings, including:
a) a substrate as a base upon which the display device is built;
b) an anode layer residing on the diamond substrate for emitting holes;
c) a hole drift layer that includes a doped diamond coating residing on the anode layer;
d) an emissive layer for emitting light and residing on the hole drift layer;
e) an electron transport layer that includes a doped diamond coating residing on the light emitting layer;
f) a cathode layer, residing on the electron transport layer, for emitting electrons that will drift towards the light emitting layer; and
g) a diamond coated encapsulation layer for sealing the display device from atmospheric moisture; wherein the multiple low temperature diamond coatings are all formed on the display device below 750° C. in a single apparatus.

Another aspect of the present invention provides for a method for fabricating a display device with multiple low temperature diamond coatings, including the following steps:
a) preparing a backplane for the display device;
b) depositing a substrate as a base upon the backplane;
c) depositing an anode layer on the substrate for emitting holes;
d) depositing a hole transport layer that includes a doped diamond coating residing on the anode layer;
e) depositing an emissive layer residing on the hole transport layer;
f) depositing an electron transport layer upon the emissive layer;
g) depositing a cathode layer upon the electron transport layer for emitting electrons that will drift towards the light emitting layer; and
h) depositing a diamond coated encapsulation layer for sealing the display device from atmospheric moisture; wherein the multiple low temperature diamond coatings are all formed on the display device below 750° C.

### ADVANTAGEOUS EFFECT OF THE INVENTION

The present invention has the advantages in that for the first time it is possible to fabricate an OLED display device at a low temperature that is more heat tolerant, that has higher power, that is faster operating, that has longer lifetime, that is bi-directional, that is more resistant to abrasion, and that has higher light conversion efficiency. Such an OLED display device can be fabricated on existing ridged amorphous, poly, continuous-grain or single crystal silicon Thin Film Transistor (TFT) backplanes [1], on the new flexible backplanes using semiconductor or organic TFT [2,3], and on flexible metal or plastic substrates [4,5]. As a result of this new OLED device structure, multiple low temperature diamond layers can be used to create a more efficient, higher power, longer lifetime device for flat panel displays, backlights and flat light sources.

### REFERENCES

1. Lih et al., “Full-color active-matrix OLED based on a-Si TFT technology” Journal of the society for Information Display, vol. 11, no. 4, SPEC. ISS., 2003, pp. 617-620.
2. Afentakis et al. “Polysilicon TFT AM-OLED on thin flexible metal substrates” Proceedings of SPIE—The International Society for Optical Engineering, vol. 5004, 2003, pp. 187-191.
3. Troccoli et al., “Amoled TFT pixel circuitry for flexible displays on metal foils” Materials Research Society Symposium—Proceedings, vol. 769, 2003, pp. 93-98.
4. Xie et al., “Fabrication of flexible organic top-emitting devices on steel foil substrates” Materials Science and Engineering B: Solid-State Materials for Advanced Technology, vol. 106, no. 3, Feb. 15, 2004, pp. 219-223.
5. Chwang et al., “Thin film encapsulated flexible organic Electroluminescent displays” Applied Physics Letters, vol. 83, no. 3, Jul. 21, 2003, p. 413.

6. Gu et al., “Transparent stacked organic light emitting devices. I. Design principles and transparent compound electrodes”, Journal of Applied Physics, vol. 86, no. 8, Oct. 15, 1999, pp. 4067-4075.

| | | | |
|---|---|---|---|
| 7. | U.S. Pat. No. 6,198,218 | Kobashi et al | 03/06/2001 |
| 8. | U.S. Pat. No. 5,334,855 | Moyer et al. | 08/02/1994 |
| 9. | U.S. Pat. No. 6,337,492 | Jones and Howard | 01/08/2002 |
| 10. | U.S. Pat. No. 5,920,080 | Jones | 07/06/1999 |
| 11. | U.S. Pat. No. 6,414,338 | Anderson | 07/02/2002 |
| 12. | U.S. Pat. No. 5,051,785 | Beetz et al | 09/24/1991 |
| 13. | U.S. Pat. No. 5,381,755 | Glesener et al | 01/17/1995 |
| 14. | U.S. Application No. | Linares and Doering | 07/17/2003 |
| | 20030131787 | | |
| 15. | U.S. Pat. No. 5,792,256 | Kucherov et al | 08/11/1998 |
| 16. | U.S. Pat. No. 6,447,851 | Gruen et al | 09/10/2002 |
| 17. | U.S. Application No. | Takeuchi et al | 08/21/2003 |
| | 20030155654 | | |
| 18. | U.S. Application No. | Hasegawa et al | 09/12/2002 |
| | 20020127405 | | |
| 19. | U.S. Pat. No. 6,340,393 | Yoshida | 01/22/2002 |
| 20. | U.S. Application No. | Regel and Cropper | |
| | 10/722309 | Filing11/25/2003 | |
| 21. | U.S. Pat. No. 4,720,432 | VanSlyke et al | 01/19/1988 |
| 22. | U.S. Pat. No. 6,208,075 | Hung et al | 03/27/2001 |
| 23. | U.S. Pat. No. 4,769,292 | Tang et al | 09/06/1988 |
| 24. | U.S. Pat. No. 5,141,671 | Bryan et al | 08/25/1992 |
| 25. | U.S. Pat. No. 5,150,006 | VanSlyke et al | 09/22/1992 |
| 26. | U.S. Pat. No. 5,151,629 | VanSlyke | 09/29/1992 |
| 27. | U.S. Pat. No. 5,405,709 | Littman and VanSlyke | 04/11/1995 |
| 28. | U.S. Pat. No. 5,484,922 | Moore et al | 01/16/1996 |
| 29. | U.S. Pat. No. 5,593,788 | Shi and Tang | 01/14/1997 |
| 30. | U.S. Pat. No. 5,645,948 | Shi et al | 07/08/1997 |
| 31. | U.S. Pat. No. 5,683,823 | Shi et al | 07/08/1997 |
| 32. | U.S. Pat. No. 5,755,999 | Shi et al | 05/26/1998 |
| 33. | U.S. Pat. No. 5,928,802 | Shi and Chen | 07/27/1999 |
| 34. | U.S. Pat. No. 5,935,720 | Chen et al | 08/10/1999 |
| 35. | U.S. Pat. No. 5,935,721 | Shi et al | 08/10/1999 |
| 36. | U.S. Pat. No. 6,020,078 | Chen et al | 02/01/2000 |
| 37. | U.S. Pat. No. 6,237,529 | Spahn | 05/29/2001 |
| 38. | U.S. Pat. No. 5,294,870 | Tang et al | 03/15/1994 |
| 39. | U.S. Pat. No. 5,851,709 | Grande et al | 12/22/1998 |
| 40. | U.S. Pat. No. 6,066,357 | Tang and Pan | 05/23/2000 |
| 41. | U.S. Pat. No. 5,776,623 | Hung et al. | 07/07/1998 |
| 42. | U.S. Pat. No. 5,276,380 | Tang | 01/04/1994 |
| 43. | U.S. Pat. No. 4,885,221 | Tsuneeda | 12/05/1989 |
| 44. | U.S. Pat. No. 5,677,572 | Hung and Tang | 10/14/1997 |

### BRIEF DESCRIPTION OF THE DRAWINGS

FIG. 1 is a schematic side view of the prior art OLED Display device.

FIG. 2 is a schematic side view of the new OLED Display device.

FIG. 3 is a schematic side view of the Deposition Chamber for the OLED Display Device.

FIG. 4 is a schematic side view of the Deposition Chamber for the OLED Display Device with moving substrate.

FIG. 5 is a schematic side view of a roll-to-roll Deposition Chamber for the OLED Display Device.

FIG. 6 is a schematic side view of a roll-to-roll Deposition Chamber for the OLED Display Device with moving substrate.

FIG. 7 is a Flow Chart showing the manufacturing steps of the present invention.

### DETAILED DESCRIPTION OF THE INVENTION

The present invention relates to an innovative method of fabricating a bi-directional OLED display device with multiple diamond layers deposited by a chemical vapor transport process at temperatures below 750° C. that would significantly increase the light conversion efficiencies and long term reliability and that can be manufactured in a continuous process.

The performance of OLEDs in display devices has been known to be highly susceptible to degradation by moisture and oxygen. For this reason, it is necessary to limit or control the amount of moisture the organic materials are exposed to, usually by encapsulating the diodes within a metal can or by sandwiching with another glass substrate containing a drying substance, thereby ensuring the continued performance of the OLED as a display. This invention provides for an OLED with transparent thin film encapsulation formed by the low-temperature deposition of diamond onto either a transparent or opaque cathode or anode contact, the formation of an OLED display on a substrate, which could be diamond, and the inclusion of a diamond hole and electron drift layer deposited at low temperature.

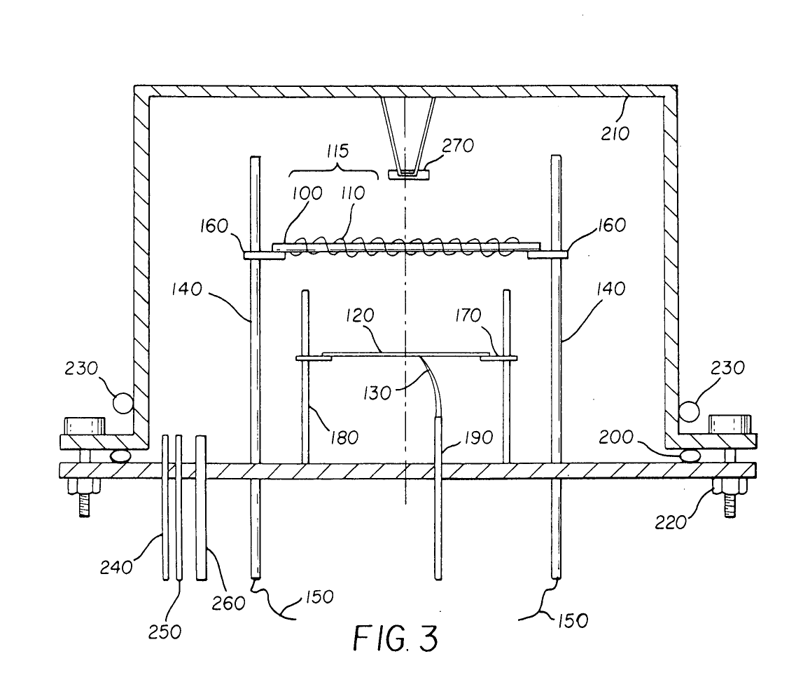

Current practice utilizes an epoxy seal to a metal can or glass plate, thereby protecting the OLED structure from moisture, oxygen, and abrasion. Application of this epoxy must be done in a chamber separate from that used to form the OLED, thereby risking the exposure of the OLED to moisture and oxygen in the atmosphere in the transfer. The diamond coating described here is envisioned as being applied in the same chamber or a connected chamber to that used to form the OLED, thereby eliminating the risk of exposure to the environment (FIG. 3). Furthermore, the unique properties of diamond provide several advantages, including superior protection from moisture, oxygen and abrasion; and heat dissipation so that the OLED can be operated at higher power or extended lifetime. Being optically transparent over a wide frequency range, diamond also permits light emission through the top and bottom of the device with the use of a transparent cathode. This would yield a larger pixel area than is currently possible with current bottom-emitting displays or with metal encapsulation.

The diamond coating described here can be used to encapsulate the OLED, thereby eliminating the risk of exposure to the environment. In addition, a low temperature diamond coating process, performed at a temperature lower than the destructive temperature of the organics, allows for OLED displays to be fabricated on both glass (rigid) and polymeric (flexible) substrates.

Also, with the low temperature diamond coating being doped, e.g. with boron, hydrogen, palladium or silicon, a p-type semiconducting layer can be created to form a hole drift layer. In addition, an n-type semiconducting layer can be achieved by doping with sulfur, phosphorus, lithium, bromine, iodine, sodium, nitrogen or a refractory metal (rhenium, tungsten, tantalum, molybdenum, niobium and vanadium). This doped structure allows for higher hole transport from the hole injection area and higher electron transport from the electron injection area to the recombination centers, because diamond has higher hole and electron mobility than organic materials, thus giving higher emission efficiencies. In addition, since the bandgap of diamond is much larger than the energy of the electron-hole recombination pairs created, these pairs cannot be reabsorbed into the diamond layer, thereby further increasing the light conversion efficiency.

The above applications take advantage of the exceptional properties of diamond, including hardness, chemical inertness, and thermal conductivity. Such an application has not been possible in the past because high temperatures were required for the deposition of diamond. This invention relates to a method for the manufacture of a display device having an Organic Light Emitting Diode (OLED) with internal components formed from doped and undoped diamond layers deposited by a chemical vapor transport process at temperatures below 750° C.

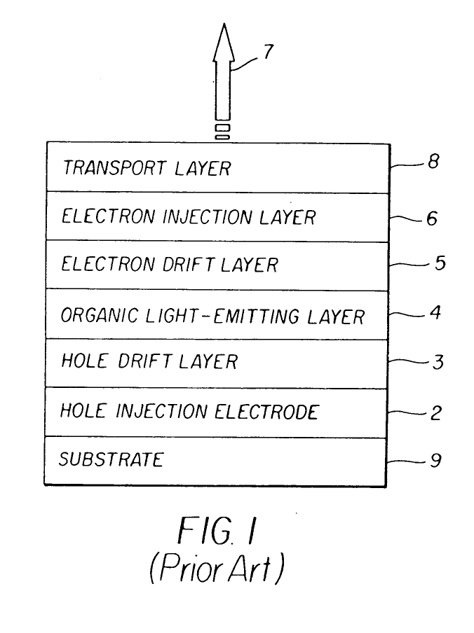

Specifically, the earlier described prior art were not able to take advantage of diamond's exceptional properties, because in some cases a diamond-like carbon having explicit different properties from diamond were used. Secondly, deposition occurred at above 800° C. which is detrimental to the organic material found in OLED devices. Thirdly, only one half of the organic structure had a diamond-like carbon coating (DLC) deposited on it, thus unwanted recombination could occur on the electron-injection side of the structure, thus reducing light conversion efficiency of the device. As shown in FIG. 1, hole drift layer 3 is coated with DLC by chemical vapor deposition (CVD), whereas electron injection layer 6 is not coated, thereby, causing unwanted electron-hole recombination to form in electron drift layer 5, which turns into heat and is therefore not resistant to high temperature degradation/deterioration.

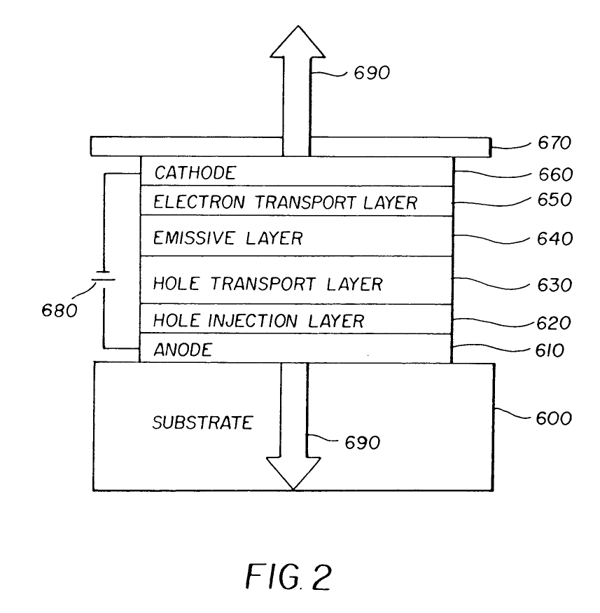

In order to more fully appreciate the construction of an OLED display device with multiple diamond coatings in the present invention, the following description is in reference to FIG. 2. One exemplary structure of the OLED display device includes, in sequence, a diamond substrate (600), an anode (610), a hole injection layer (HIL) (620), a hole transport layer (HTL) (630), an emissive layer (EL) (640), an electron transport layer (ETL)(650), and a cathode (660). Since the OLED display device is sensitive to moisture or oxygen, or both, it is sealed within an encapsulation layer (670).

In this embodiment, the OLED display device is connected to a voltage/current source (680) through electrical conductors. The OLED display device is operated by applying an electric potential generated by a voltage/current source (680) between the pair of electrical conductors connected to anode (610) and cathode (660), such that the anode (610) is at a more positive potential with respect to the cathode (660). The electrical potential across the OLED display device causes holes (positively charged carriers) to be injected from the anode (610) into the EL (640), and causes electrons (negatively charged carriers) to be injected from the cathode (660) into the EL (640). Subsequently, these electrons and holes recombine in the EL (640) to produce light emissions (690), which are observed via the transparent anode (610) and cathode (660) electrode or electrodes. The properties of the EL (640) in the OLED display device can be optimized to achieve the desired performance of any feature; for example, light transmission through the device, driving voltage, luminance efficiency, light emission color, manufacturability, device stability, and so forth. While not shown in FIG. 2, the OLED display device can optionally include an electron injection layer (EIL) between the ETL (650) and the cathode (660).

The ETL (650) and the HTL (630) of this invention are n-type doped and p-type doped, with the n-typed doped layer deposited adjacent to the cathode and the p-type doped layer-adjacent to the anode. “n-type” denotes that electrons substantially carry the electrical current, while “p-type” indicates that the electrical current is substantially carried by the holes. The n-type doped layer includes a host material and at least one n-type dopant. The host material for the n-type doped layer in this invention is diamond, but other host materials can include another semiconductor material, a small molecule material or a polymeric material, or combinations thereof, and it is preferable for the host material to support electron transport. The p-type doped layer includes a host material and at least one p-type dopant. The host material for the p-type doped layer in this invention is diamond, but can include another semiconductor material, a small molecule material or a polymeric material, or combinations thereof, and it is preferable that it can support hole transport.

In conventional OLED display devices, the n-type dopant concentration and the p-type dopant concentration are preferably in the range of 0.01-10 vol. %. The total thickness of each doped layer is typically less than 100 nm, and preferably in the range of 1 to 10 nm. The host materials customarily used for the n-type layer are metal chelated oxinoid compounds, including chelates of oxine, such as tris aluminum and various butadiene derivatives. The host materials conventionally used for the p-type layer include aromatic tertiary amines having at least one trivalent nitrogen that is bonded only to carbon atoms, at least one of which is a member of an aromatic ring. In one form the aromatic tertiary can be an arylamine, such as a monoarylamine, diarylamine, triarylamine, or a polymeric arylamine. A more preferred class of aromatic tertiary amines is those that include at least two aromatic tertiary amine moieties. The n-type layer can be created by in-situ doping of the diamond layer during deposition with a refractory metal (rhenium, tungsten, tantalum, molybdenum, niobium, and vanadium), as taught in U.S. Pat. No. 6,414,338, or lithium, antimony, bismuth, arsenic, scandium, sulfur or phosphorous, as taught in U.S. Pat. Nos. 5,051,785; 5,381,755; and 20030131787. An n-type layer also can be created by ion implanting lithium, nitrogen and sulfur or sputtering arsenic and sulfur, as disclosed in U.S. Pat. Nos. 5,792,256; 6,447,851; 20030155654; 20020127405 and 6,340,393. The p-type layer can be created by in-situ doping of the diamond layer during deposition, for example, by the presence of a boron source such as diborane (B₂H₆), as taught in U.S. Pat. No. 6,198,218.

In the present invention, all the materials used for the fabrication of the OLED display device are substantially transparent to the emitted light. When activated, light is emitted through the transparent substrate (600), anode (610), HIL (620), HTL (630), EL (640), ETL (650), cathode (660) and transparent encapsulation (670). The device configuration shown in FIG. 2 can be used in a very simple structure comprising a single anode and cathode or a more complex device, such as passive and active matrix devices. A passive matrix display is comprised of orthogonal arrays of anodes and cathodes that form pixels at their intersections, wherein each pixel acts as an OLED display device that can be electrically activated independently of other pixels. In an active matrix OLED display device, an array of device pixels is formed in contact with thin film transistors (TFTs), such that each pixel is activated and controlled independently by one or more TFTs. Each device pixel is provided with a means for accepting the necessary voltage to operate the OLED display device. The present invention can be used in full color matrix displays by combining individual OLED display devices of red, green and blue to serve as a RGB pixel. This present invention can be advantageously used for applications such as backlights for LCD, flat light sources for general area lighting, as heads-up displays, micro displays, and color FPD such as in cell phones, PDAs, computer screens, television sets, etc. In addition, the OLED display device described within can be connected to an optical fiber's emitting end, wherein the optical fiber is connected to the active matrix backplane to form an active matrix display device. When multiple OLED display devices are connected to a plurality of optical fibers that emit red, green and blue colored light, the combination can serve as an RGB pixel.

The OLED display device is typically provided over a supporting substrate where either the cathode or anode of the OLED can be in contact with the supporting substrate. The electrode in contact with the supporting substrate is conveniently referred to as the bottom electrode. Conventionally, the bottom electrode is the anode, but this invention is not limited to that configuration. The substrate can either be light transmissive or opaque, depending on the intended direction of the light emission. When the light transmissive property is desirable for viewing the light emission through the substrate, transparent rigid or flexible supporting substrates are commonly employed. For applications where the light emission is viewed through the top electrode, the transmissive characteristic of the bottom support is immaterial, and therefore can be light transmissive, light absorbing or light reflective. Supporting substrates used in this case include, but are not limited to glass, plastic, semiconductor materials such as silicon, a ceramic and circuit board materials. However, it is preferable to provide a light transparent top electrode in this device configuration.

In the present invention shown in FIG. 2, wherein a bi-directional device is required, both the top and bottom electrode should be transparent, as well as the substrate. In this case the substrate of choice for the present invention would be single-crystal insulating diamond, but polycrystalline diamond or a diamond-like carbon could also be used. Where the insulating diamond coating have a well-defined Raman spectral single peak at 1332 cm⁻¹ for a pure or nearly pure diamond coating, and a Raman spectral broad band in the range of 1357 to 1580 cm⁻¹ having a single peak within the range of 1357 to 1580 cm⁻¹, for a diamond-like coating. The insulating diamond substrate can be formed on, or connected to, an active or passive matrix backplane in order to form an active matrix or passive matrix display device, which is fabricated on either a rigid or a flexible transparent supporting substrate consisting of a semiconductor material, a polymer, a metal, or a glass. Here, the crystalline insulating diamond layer is formed by Chemical Vapor Transport Deposition (CVTD) at temperatures below 750° C., as described in U.S. Ser. No. 10/722,309. It provides excellent resistance to high temperature, with unsurpassed corrosion and erosion resistance. It has excellent optical transparency from infrared to ultraviolet and, as a semiconductor, diamond has a saturation velocity much greater than for Si, GaAs and InP and high carrier mobilities, (electron mobility of 2200 cm²/Vs and hole mobility of 1600 cm²/Vs). Diamond's unique properties make it an excellent candidate on which to build an active matrix backplane on the side away from the OLED device.

When light emission is viewed through the anode (610), the anode should be transparent or substantially transparent to the emission wavelengths of interest. A common transparent anode material used for OLEDs is indium-tin oxide (ITO), but other metal oxides can be used including, but not limited to, tin oxide, aluminum- or indium-doped zinc oxide (IZO), magnesium-indium oxide, nickel-tungsten oxide, or a combination thereof. In addition to these oxides, a metal nitride such as gallium nitride, metal selenide such as zinc selenide, or a metal sulfide such as zinc sulfide, can be used as an anode (610), as well as materials selected from the group consisting of gold, nickel, platinum, and molybdenum. For conditions where the light emission is only viewed through the cathode electrode, the transmissive characteristics of the anode are irrelevant and any transparent, opaque or reflective conductive material can be used. Typical anode materials have a high work function of 4.1 eV or greater. They are commonly deposited by vacuum evaporation, but can also be deposited by sputtering, chemical vapor deposition (CVD) or electrochemical means.

While not necessary, it is often useful to have a HIL (620) between the anode (610) and the HTL (630). The HIL (620) material can serve to facilitate the injection of holes into the HTL. Suitable materials for use in a HIL (620) include, but are not limited to, porphyrinic compounds as described in U.S. Pat. No. 4,720,432, and plasma deposited fluorocarbon polymers as described in U.S. Pat. No. 6,208,075.

The hole transport layer (630) in conventional OLED display devices is formed from a single aromatic tertiary amine or a mixture of two or more such amines. This aromatic tertiary amine can be a crystalline arylamine, such as a monoarylamine, diarylamine or triarylamine, or a polymeric arylamine. In this present invention the HTL (630) is formed from p-type (probably boron doped) single crystalline or polycrystalline structured semiconducting diamond, (a diamond-like carbon can also be used) deposited by CVT at temperatures below 750° C. The p-type diamond HTL (630) also could be deposited by hot filament or plasma chemical vapor deposition, laser ablation or other deposition techniques well known in the art. It is preferred that the concentration of the diborane (B₂H₆) gas introduced in the chamber is approximately 1 to 20-volume ppm. The boron concentration of the doped diamond coating is on the order of 1.0×10¹⁹ to 1.0×10²¹/cm³. The resulting HTL (630) should have a bandgap energy level greater than the energy level of the exciton (electron-hole pairs) created by the recombination of the injected electron and holes in the emissive layer. This prevents the electron-hole recombination pairs from being reabsorbed by drifting into the HTL (630). As a result, the light conversion efficiency is further increased. Other materials such as hydrogen, palladium or silicon, also can be used to create a p-type semiconducting hole transport layer.

The emissive layer (EL) (640) includes a luminescent or fluorescent material wherein electroluminescence is produced as a result of electron-hole recombination. The EL (640) can be comprised of a single compound, but more commonly consists of a host material doped with one or more guest compounds wherein light emission comes primarily from the dopant and can be of any color. The host material in the EL (640) can include any combination of chemical compounds that support electron-hole recombination. The dopant is usually a highly fluorescent dye, although phosphorescent components such as transition metals are also useful. Dopants are typically incorporated from 0.01 to 10% by weight into the host material. In addition to crystalline materials, polymers such as polyfluorenes and polyvinylarylenes (for example, poly (p-phenylenevinylene), PPV) can also be used as the host material. Small molecule dopants can be dissolved in the polymeric host, or by copolymerization with the host polymer. Light emitting hosts and dopants known to be of use include, but are not limited to, those disclosed in U.S. Pat. Nos. 4,769,292; 5,141,671; 5,150,006; 5,151,629; 5,405,709; 5,484,922; 5,593,788; 5,645,948; 5,683,823; 5,755,999; 5,928,802; 5,935,720; 5,935,721; and 6,020,078. Crystalline organic materials can be deposited by a vapor-phase method such as sublimation, from a melt, or from a solution that may contain an optional binder to improve film formation. Polymeric materials can be deposited from a solution, by sputtering or thermal transfer from a donor sheet. When depositing by sublimation a “boat” usually made from tantalum is used to provide the vapor needed for deposition, as described in U.S. Pat. No. 6,237,529. Patterned deposition can be achieved using a shadow mask, such as an integral shadow mask (disclosed in U.S. Pat. No. 5,294,870), or a spatially defined thermal dye transfer from a donor sheet (U.S. Pat. No. 5,851,709), or by an inkiet method (U.S. Pat. No. 6,066,357). The electron transport layer in conventional OLED display devices is usually formed from metal chelated oxinoid compounds, including chelates of oxine itself. Such compounds help to inject and transport electrons. Other electron transporting materials include various butadiene derivatives and heterocyclic optical brighteners. In some instances the ETL (650) and the EL (640) (shown in FIG. 2) are combined into a single layer that provides both light emission and electron transport. For example, PPV as the polymeric light-emitting layer also provides electron transport when used with HTL PEDOT-PSS. In this present invention the ETL (650) is formed from n-type single crystalline or polycrystalline semiconducting diamond, diamond-like carbon could also be used) deposited by CVT at temperatures below the destructive temperatures of the organic materials. The resulting ETL (650) should have a bandgap energy level greater than an energy level of the exciton (electron-hole pairs) created by the recombination of the injected electron and holes in the emissive layer. This prevents the electron-hole recombination pairs from being reabsorbed by drifting into the ETL (650); as a result, the light conversion efficiency is further increasing.

The ETL (650) is formed by in-situ doping of diamond with sulfur, phosphorus, lithium, bromine, iodine, sodium, nitrogen, or a refractory metal (rhenium, tungsten, tantalum, molybdenum, niobium, vanadium). The n-type doped diamond ETL (650) also could be deposited by hot filament or plasma chemical vapor deposition, laser ablation, or other techniques that permit controlled doping and are well known in the art.

The cathode (670) plays an important role in bi-directional OLED display device. Here, the light emission is also transmitted through the cathode (670); thus, the cathode (670) must be transparent or nearly transparent. For such applications, one must use a transparent conductive oxide, a very thin metal layer, or a combination of these materials. The materials must also have good film forming properties to ensure good contact with the underlying ETL (650), to promote electron injection at low voltages, and to have good electrical stability. Useful cathode materials should contain a low work function metal (<4.0 eV) or metal alloy. Optically transparent cathodes have been described in more detail in U.S. Pat. No. 5,776,623. Cathode materials layers can be deposited by evaporation, sputtering, laser ablation or CVD and patterned by well known methods including, but not limited to, through—mask deposition—and integral shadow masking as described in U.S. Pat. No. 5,276,380. If light is viewed solely through the anode, the cathode can be comprised of nearly any conductive material. One preferred cathode material is comprised of a Mg:Ag alloy wherein the percentage of silver is in the range of 1 to 20%.

Since most OLED display devices are sensitive to moisture or oxygen, or both, they are commonly sealed in an inert atmosphere along with a desiccant. In some cases, barrier layers such as SiOₓ, Teflon, and alternating inorganic/polymeric layers are used in the art of encapsulation. Traditional methods for encapsulation and desiccation include, but are not limited to, those described in U.S. Pat. No. 6,066,357. In this present invention (FIG. 2), the encapsulation of choice is an insulating single crystal diamond coating (but polycrystalline diamond or diamond-like carbon can also be used), which is used to seal the OLED display device from atmospheric moisture. This crystalline insulating diamond can be formed by CVTD at temperatures below 200° C. as described in Regel and Cropper (U.S. Ser. No. 10/722,309). This insulating diamond encapsulation layer is formed on the cathode. It provides excellent resistance to high temperature, with unsurpassed corrosion and erosion resistance. It has excellent optical transparency from infrared to ultraviolet, high thermal conductivity, low specific heat, high transmittance, and refractive index.

In the present invention (referring to FIG. 2), the deposition of diamond layers for the substrate (600), HTL (630), ETL (650) and the encapsulation (670) are all conducted at temperatures between 100° C.-750° C.

The manufacturing process for the present invention of an OLED display device with multiple diamond coatings deposited at temperatures below 750° C. can be best understood by referring to FIG. 3. It is a side view of the equipment needed to manufacture the OLED display device using a new Chemical Vapor Transport (CVT) technique (described in U.S. Ser. No. 10/722,309) combined with a traditional vacuum deposition system. The substrate (120) during the diamond deposition stages, is placed some distance from a single wire-wrapped graphite assembly component (115) (which is a deposition source), which consists of a high-melting metal wire (110), typically platinum, wrapped around a graphite rod (100), so as to permit the graphite to operate at a sufficiently high temperature to produce the diamond precursor chemicals while maintaining the substrate (120) at the desired low temperature. The wire-wrapped graphite assembly component (115) is firmly attached at the ends to the two feed-through poles (140), which are connected outside the chamber to a variable voltage power supply (not shown) that includes voltage and current measuring meters on the variable voltage power supply wires (150). During the non-diamond deposition stages the element assembly holder (270) is positioned over the substrate (120) and the wire-wrapped graphite assembly component (115) is moved away from the substrate (120). This allows for the deposition of the anode (610), cathode (660) and emissive layers (640) (as shown in FIG. 2) using standard vacuum deposition processes known in the art, such as vapor-phase sublimation as described in U.S. Pat. No. 6,237,529 for the emissive layer (640), and by evaporation, sputtering or chemical vapor deposition for the anode (610), and as described in U.S. Pat. Nos. 4,885,221 and 5,677,572 for the cathode (660). Depending on the deposition process in use the substrate (120) is moved either above or below the element assembly holder (270) position. The height adjusting devices (160) for connecting the wire-wrapped graphite assembly component (115) can easily be slid along the graphite feed-through rods (140) to permit adjustment of the spacing between the wire-wrapped graphite assembly component (115) and the substrate (120). The substrate (120) is attached to the substrate height adjustment rods (180) by substrate holder (170). Again, this substrate holder (170) can easily be moved up and down the substrate height adjustment rods (180). The substrate height adjustment poles (180) are placed 90° from the graphite feed-through poles (140), so that the substrate (120) is crossways to the wire-wrapped graphite assembly component (115). This substrate may be below the graphite rod (100), above the graphite rod (100), beside it, or surrounding it. A thermocouple (130) is placed on the opposite side of the substrate (120) and in contact with it. The thermocouple (130) wires are attached to the thermocouple holder (190) that feeds through to the external measurement electronics that convert the millivolt signal to temperature. The water-cooled chamber cover (210) is placed over this assembly and bolted with chamber bolts (220) to the bottom plate with a rubber o-ring (200) in the flange so as to make the chamber gas tight.

During the diamond deposition process, the cooling water hoses (230) are connected to chamber cover (210) and the cooling water turned on. The chamber is evacuated for an hour or more via vacuum tubing (260) connected to a vacuum pump (not shown). A valve (not shown) in the vacuum tubing (260) is closed and another valve (not shown) in the hydrogen line (240) is opened to admit hydrogen gas to approximately one atmosphere pressure within the chamber. The pressure is read via a pressure gauge (not shown) or transducer (not shown) connected to air line (250). The chamber is alternately evacuated and filled with hydrogen so as to flush out traces of air and moisture. Finally, the chamber is filled with hydrogen to the desired pressure, approximately 0.1 atmosphere, and the valve to the hydrogen supply closed. At this time the chamber is completely sealed and is open only to the pressure gauge. Electric power is applied to the graphite rod (100) through the graphite feed-through rods (140). The voltage and current are slowly increased until thermocouple (130) indicates that the desired substrate temperature has been reached. The graphite temperature may be read by an optical pyrometer through a view window (not shown) in the chamber cover (210). During a diamond deposition run, which may be minutes to days in length, many parameters are monitored, including pressure, substrate temperature, and the voltage and current to the graphite rod. Typically, negligible variations in these parameters are detected. At the completion of a deposition run, the power to the graphite is switched off. After cooling has taken place for an hour or more, air is admitted to the chamber through the air line (250), the chamber is opened, and the substrate removed. Greater details for depositing diamond on various substrates can be found in and are incorporated by reference in U.S. Ser. No. 10/722,309.

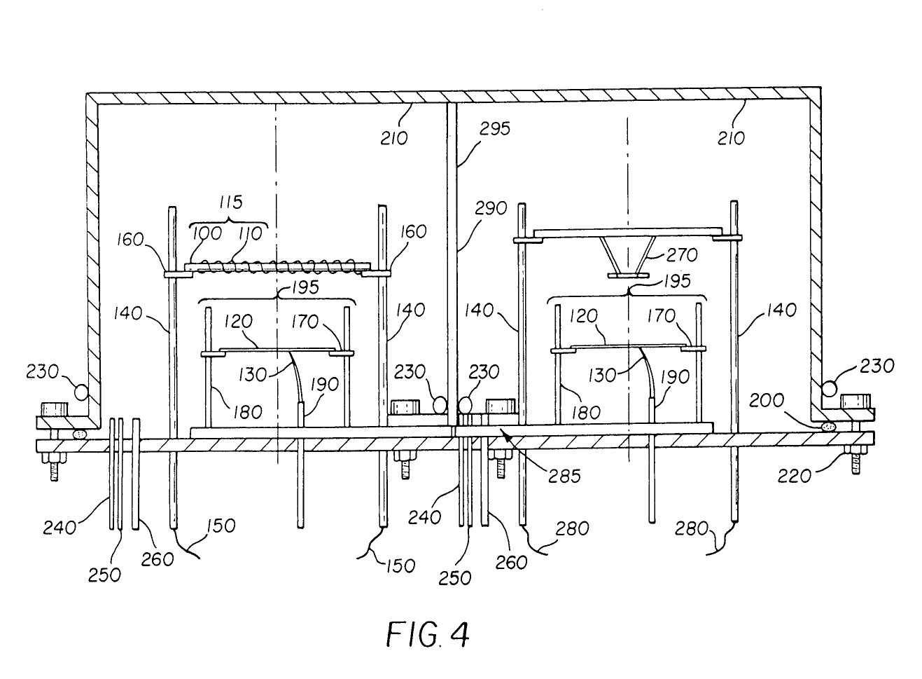

The present invention of an OLED display device with multiple diamond coatings deposited at temperatures below 750° C. can also be manufactured by the process shown in FIG. 4 where, instead of keeping the substrate (120) at a constant location and varying the deposition sources: a) the single wire-wrapped graphite assembly component (115), and b) one found inside of element assembly holder (270), but not shown; the substrate (120) is now moved from one section of the chamber to another, while the deposition sources associated with (115) and (270) are fixed. In this embodiment of the manufacturing process the two deposition chambers are almost the same except for the deposition source associated with (115) and (270) and the drive electronics (150 and 280). There is also a vacuum door (290) in a wall (295) between the two chambers that allows a substrate assembly (195) to slide along a connecting path (285) between the two chambers. The processing steps described above are all the same.

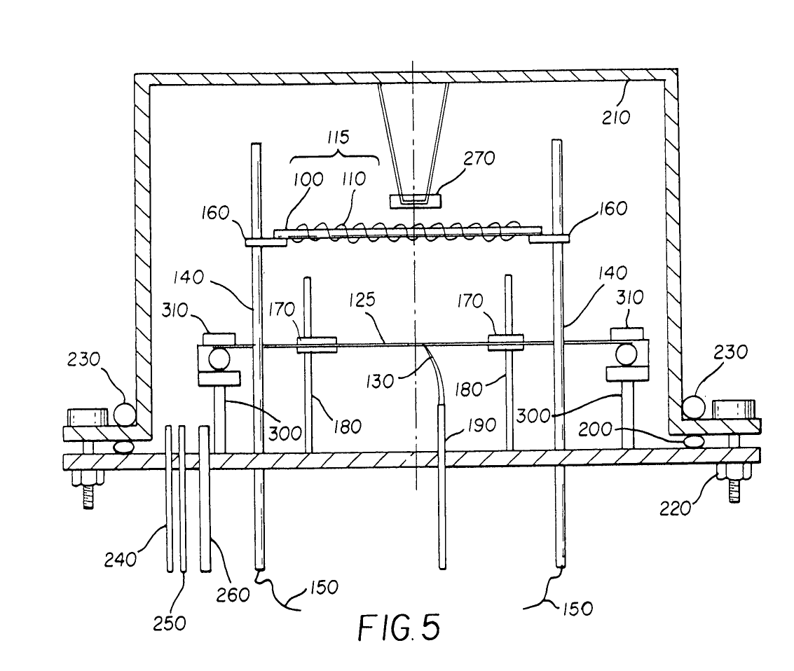

The present invention of an OLED display device with multiple diamond coatings deposited at temperatures below 750° C. can also be manufactured from a process shown in FIG. 5 where, in this case, the substrate (125) is flexible and the deposition systems are movable. During the non-diamond deposition stages the element assembly holder (270) is positioned into place over the substrate (120) and the wire-wrapped graphite assembly component (115) is moved away from the substrate. This allows for the deposition of the anode, cathode and emissive layers using standard vacuum deposition processes. The flexible substrates (125) in this case are mounted within the roll-to-roll case holder (310), which is held in place by the roll-to-roll holder (300) that allows the flexible substrate to be situated some distance from the deposition systems, the element assembly holder (270) or the wire-wrapped graphite assembly component (115). The flexible substrate (125) may be below, above, beside, or surrounding the graphite rod (100) or the element assembly holder (270). Thus, the flexible substrate (125) can be placed in any position with reference to the deposition systems and not only below as shown in FIG. 5. All other components within the chamber are the same as that shown in FIG. 3 for manufacturing the OLED display device.

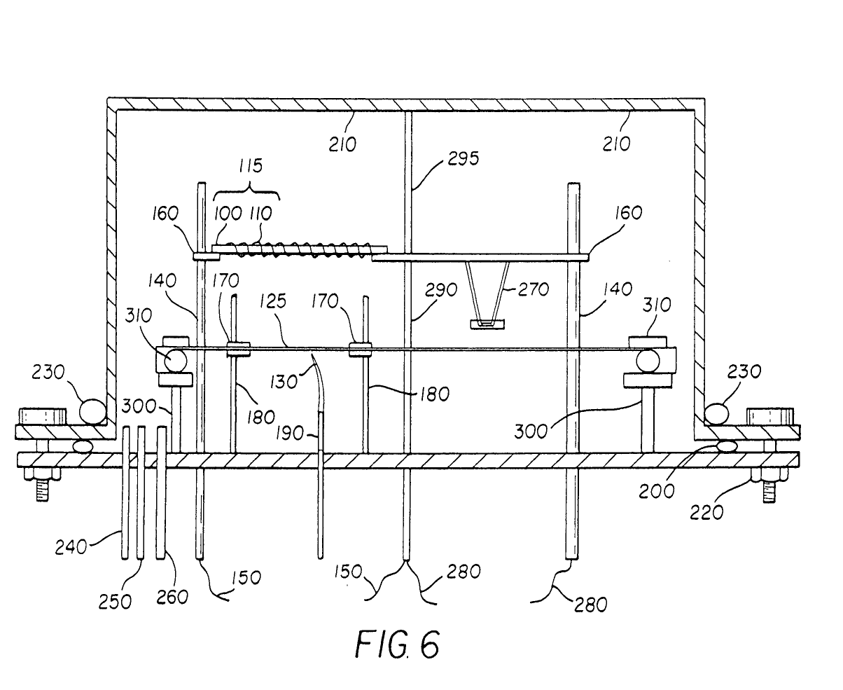

The present invention of an OLED display device with multiple diamond coatings deposited at temperatures below 750° C. can also be manufactured using the apparatus shown in FIG. 6 wherein the flexible substrate (125) is moved between the two sections of the chamber, while the deposition sources (115) and (270) remain fixed. In this exemplary embodiment of the manufacturing process there is a vacuum door (290) between the two chambers separated by a wall (295) that allows the flexible substrate (125) to move between the two chambers during deposition of various layers. All other components within the chamber are the same as that shown in FIG. 4 for manufacturing the OLED display device.

Conventional OLED display devices are manufactured by many different techniques know in the field, one such process is as follows: A 1-mm thick glass substrate coated with a transparent ITO conductive layer is cleaned and dried using a commercial glass scrubber tool. The thickness of the ITO is about 42 nm and its sheet resistance is about 68 Ω/square. The ITO surface is subsequently treated by an oxidative plasma to condition the surface as an anode. A 1-nm thick CFₓ layer is deposited onto the clean ITO surface for the HIL by decomposing CHF₃ gas in an RF plasma. The substrate is transferred into a second chamber for sublimation vacuum deposition, from a heated boat, of all the other layers (HTL, EL, ETL and cathode). The vacuum in this second chamber is approximately 10⁻⁶ Torr. A 75-nm thick layer of NPB is deposited to form the HTL. This is followed by a deposition of a 60-nm thick layer of Alq to form the ETL containing the EL. Finally, a 210 nm thick layer of Mg:Ag is deposited to form the cathode. After deposition of these layers, the resulting OLED display device is transferred from the deposition chamber into a dry box for encapsulation in another chamber.

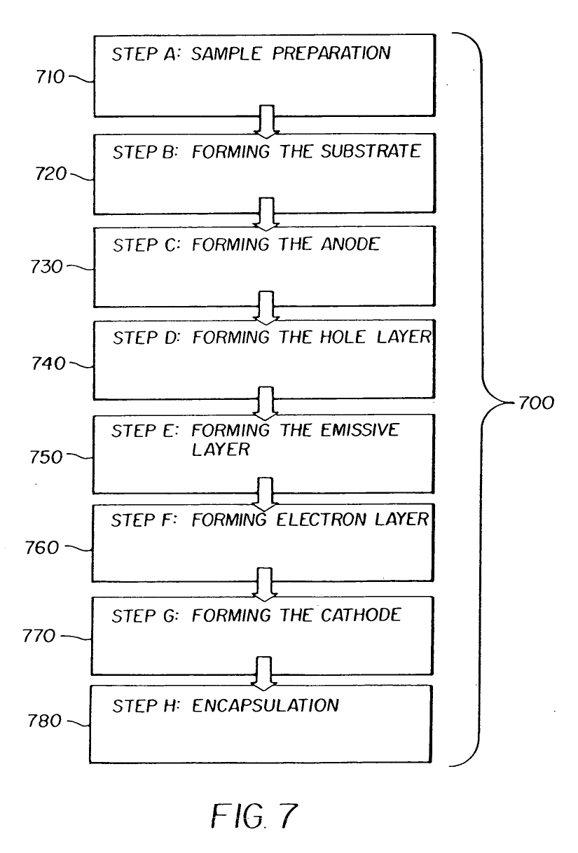

Regarding the present invention, the OLED display device manufacturing Process Flow (700) is shown in FIG. 7. One such embodiment of the Process Flow (700) is: In step A—Sample Preparation (710), the ridged (or flexible) backplane is prepared by cleaning and drying using a commercial glass scrubber tool. The backplane could be made from, but not limited to, glass, polymer, metal, or semiconductor, if needed, an additional rinsing in methanol and drying is performed. To increase the nucleation density (particles/area) of diamond, the backplane is sometimes scratched with diamond powder by suspending it in a suspension of diamond powder in an ultrasonic bath. (This is not necessary to obtain diamond, but only in some cases to increase the number of diamond particles per unit area.) The graphite rod (100) is cleaned by rinsing with methanol and then dried. It is wrapped with the desired high-melting metal wire (110), typically platinum, to form a single wire-wrapped graphite assembly component (115).

In step B—Forming the substrate (720), the backplane is attached to the substrate support rods (180) by substrate holder (170) and its position is adjusted to approximately 15 mm away from the wire-wrapped graphite assembly component (115). A 0.5-mm to 1-mm layer of transparent insulating diamond is deposited (as described in U.S. Ser. No. 10/722,309) at temperatures below 750° C.

In step C—Forming the Anode (723), the backplane with its transparent insulating diamond substrate are moved along the connecting path (285) to the second chamber (shown in FIG. 4) for deposition of the transparent, high work function ITO layer by sputtering. Approximately 42 nm of ITO is deposited with a sheet resistance of approximately 68 Ω/square.

In step D—Forming the Hole Layer (740), the backplane, with its transparent insulating diamond substrate and transparent, high work function ITO layer is prepared for the HIL by evacuating and flushing the chamber with hydrogen at least three times.

A 1-nm thick layer of CFₓ is deposited onto the clean ITO surface by decomposing CHF₃ gas in a RF plasma. The backplane, with its transparent insulating diamond substrate, anode and HIL, is moved back along the connecting path (285) to the first chamber (shown in FIG. 4) for deposition of the HTL by CVT. Less than 1-μm thick layer of transparent p-type diamond is deposited at temperatures below 750° C. (as described in U.S. Ser. No. 10/722,309), at approximately 0.1 atmosphere.

In step E—Forming the Emissive Layer (750), the backplane, with its transparent insulating diamond substrate, anode, HIL and HTL, is transferred back into the second chamber (shown in FIG. 4) for sublimation vacuum deposition, from a heated boat, of the EL. The vacuum in this second chamber is adjusted to approximately 10⁻⁶ Torr. A 60-nm thick layer of Alq is deposited to form the EL.

In step F—Forming the Electron Layer (760), the backplane, with its transparent insulating diamond substrate, anode, HIL, HTL and EL, is transferred back into the first chamber (shown in FIG. 4) for deposition of the ETL by CVT. Less than 1-μm thick layer of transparent n-type diamond is deposited at temperatures below 200° C. by replacing the platinum in the wire-wrapped graphite assembly component (115) (which consist of platinum metal wire wrapped around a graphite rod) with nickel, in combination with hydrogen gas (as described in U.S. Ser. No. 10/722,309). It is also possible to replace the nickel wire with a 0.010-inch rhenium wire and achieve the same results.

In step G—Forming the Cathode (770), the backplane, with its transparent insulating diamond substrate, anode, HIL, HTL, EL and EIL, is transferred along the connecting path (285) to the second chamber (shown in FIG. 4) for deposition of the transparent cathode by thermal evaporation from a heated tantalum boat. Approximately 0.5 nm of lithium fluoride (LiF) followed by 120 nm of aluminum is deposited to form the cathode. (If an opaque cathode is needed, then a 210-nm thick layer of Mg:Ag is deposited to form the cathode).

In step H—Encapsulation (780), the backplane, with its transparent insulating diamond substrate, anode, HIL, HTL, EL, EIL and cathode, is transferred back across the connecting path (285) to the first chamber (shown in FIG. 4) for deposition of the transparent encapsulation by CVT. A 0.1-mm to 1-mm layer of transparent insulating diamond is deposited as described in Regel and Cropper (U.S. Ser. No. 10/722,309) at temperatures below 200° C. This encapsulation provides high thermal conductivity and high transmittance. In addition, it provides excellent resistance to high temperature, with unsurpassed corrosion and erosion resistance.

This process of encapsulating the device within the same manufacturing equipment avoids the necessity of transferring the OLED display device from the deposition chamber into a dry box for encapsulation in another chamber and risking exposure to moisture during the transfer. At the end of the manufacturing process the complete device is removed from the chamber and connected to a voltage/current source.

Another embodiment of the Process Flow is: In step A—Sample Preparation (710), the ridged (or flexible) backplane is prepared by cleaning and drying using a commercial glass scrubber tool. To increase the nucleation density (particles/area) of diamond, the backplane is scratched with diamond powder by suspending it in a suspension of diamond powder in an ultrasonic bath. The graphite rod (100) is cleaned by rinsing with methanol and then dried. It is wrapped with platinum wire (110), to form a single wire-wrapped graphite assembly component (115).

In step B—Forming the substrate (720), the backplane is attached to the substrate support rods (180) by substrate holder (170) and its position is adjusted to approximately 15 mm away from the wire-wrapped graphite assembly component (115). A 0.5-mm to 1-mm layer of transparent insulating diamond is deposited at temperatures below 750° C.

In step C—Forming the Anode (723), the backplane with its transparent insulating diamond substrate are moved along the connecting path (285) to the second chamber (shown in FIG. 4) for deposition of the transparent, high work function ITO layer by sputtering. Approximately 42 nm of ITO is deposited with a sheet resistance of approximately 68 Ω/square.

In step D—Forming the Hole Layer (740), the backplane, with its transparent insulating diamond substrate and transparent, high work function ITO layer is prepared for the HIL by evacuating and flushing the chamber with hydrogen at least three times.

A 1-nm thick layer of CFₓ is deposited onto the clean ITO surface by decomposing CHF₃ gas in a RF plasma. The backplane, with its transparent insulating diamond substrate, anode and HIL, is moved back along the connecting path (285) to the first chamber (shown in FIG. 4) for deposition of the HTL by CVT. Less than 1-μm thick layer of transparent p-type diamond is deposited at temperatures below 750° C. by CVT of boron soaked graphite rod at approximately 0.1 atmosphere.

In step E—Forming the Emissive Layer (750), the backplane, with its transparent insulating diamond substrate, anode, HIL and HTL, is transferred back into the second chamber (shown in FIG. 4) for sublimation vacuum deposition, from a heated boat, of the EL. The vacuum in this second chamber is adjusted to approximately 10⁻⁶ Torr. A 60-nm thick layer of Alq is deposited to form the EL.

In step F—Forming the Electron Layer (760), the backplane, with its transparent insulating diamond substrate, anode, HIL, HTL and EL, is transferred back into the first chamber (shown in FIG. 4) for deposition of the ETL by CVT. Less than 1-μm thick layer of transparent n-type diamond is deposited at temperatures below 200° C. by CVT using a 0.010-inch rhenium wire-wrapped graphite assembly component (115), in combination with hydrogen gas.

In step G—Forming the Cathode (770), the backplane, with its transparent insulating diamond substrate, anode, HIL, HTL, EL and EIL, is transferred along the connecting path (285) to the second chamber (shown in FIG. 4) for deposition of the transparent cathode by thermal evaporation from a heated tantalum boat. Approximately 0.5 nm of lithium fluoride (LiF) followed by 120 nm of aluminum is deposited to form the cathode.

In step H—Encapsulation (780), the backplane, with its transparent insulating diamond substrate, anode, HIL, HTL, EL, EIL and cathode, is transferred back across the connecting path (285) to the first chamber (FIG. 4) for deposition of the transparent encapsulation by CVT. A 0.1-mm to 1-mm layer of transparent insulating diamond is deposited by CVT at temperatures below 200° C. This encapsulation provides high thermal conductivity, high transmittance, excellent resistance to high temperature, and unsurpassed corrosion and erosion resistance.

This top-down manufacturing process can also be reversed so that the display device is manufactured backwards or bottom up, starting with a 0.1-mm to 1-mm layer of transparent insulating diamond as a substrate (720), followed in sequence by deposition of the transparent cathode (770), the ETL (760), the EL (750), the HTL and the HIL (740), the anode (730), and finally an encapsulation layer. The preferred embodiment is a new OLED display device with multiple diamond coatings deposited by a chemical vapor transport process at temperatures below 750° C. and methods for the manufacture of such a display on both rigid and flexible substrates. The particular coating technique described here is primarily intended to illustrate that such a device is possible, with the details dependent on the application. It is likely that other techniques or conditions can be developed that will produce OLED display devices with multiple diamond coatings at temperature below 750° C., but would still be within the realm of the present invention.

Hence, the invention has been described with reference to a preferred embodiment. However, it will be appreciated that a person of ordinary skill in the art can effect variations and modifications without departing from the scope of the invention.

### PARTS LIST

002 Prior art electrode for hole injection
003 Prior art hole drift layer
004 Prior art organic light emitting layer
005 Prior art electron drift layer
006 Prior art electrode for electron injection
007 Prior art emitted light
008 Prior art transparent layer
009 Prior art substrate
100 Graphite rod
110 High-melting metal wire
115 Single wire-wrapped graphite assembly component
120 Substrate
125 Flexible substrate
130 Thermocouple
140 Graphite feed-through poles
150 Variable voltage power supply leads
160 Height adjusting device
170 Substrate holder
180 Substrate height adjustment pole
190 Thermocouple holder
195 Substrate assembly
200 Rubber o-ring
210 Chamber cover
220 Chamber bolts
230 Cooling water hose
240 Hydrogen tube
250 Air tube
260 Vacuum tube
270 Element assembly holder
280 Drive electronics
285 Connecting path
290 Vacuum door
295 Separation wall
300 Roll-to-roll holder
310 Roll-to-roll case holder
600 diamond substrate
610 Anode
620 Hole injection layer
630 N-type diamond hole transport layer
640 Emissive layer
650 P-type diamond electron transport layer
660 Cathode
670 Insulating diamond encapsulation layer
680 Voltage/current source
690 Light emissions
700 Manufacturing Process Flow
710 Step A Sample Preparation
720 Step B Forming the Substrate
730 Step C Forming the Anode
740 Step D Forming the Hole Layer
750 Step E Forming the Emissive Layer
760 Step F Forming the Electron Layer
770 Step G Forming the Cathode
780 Step H Encapsulation

What is claimed is:

1. A display device having multiple diamond coatings, comprising:
a) a substrate as a base upon which the display device is built;
b) an anode layer residing on the substrate for emitting holes;
c) a hole drift layer that includes a diamond coating residing on the anode layer;
d) an emissive layer for emitting light and residing on the hole drift layer;
e) an electron transport layer that includes a diamond coating residing on the emissive layer;
f) a cathode layer, residing on the electron transport layer, for emitting electrons that will drift towards the emissive layer; and
g) an encapsulation layer for sealing the display device from atmospheric moisture.

2. The display device claimed in claim 1, wherein the hole drift layer is doped with a P-type dopant.

3. The display device claimed in claim 2, wherein the hole drift layer is doped with elements selected from the group consisting of boron, hydrogen, palladium, or silicon.

4. The display device claimed in claim 1, wherein the hole drift layer is either a single or highly polycrystalline structure.

5. The display device claimed in claim 1, wherein the hole drift layer has a bandgap energy level greater than an energy level of electron-hole recombination pairs that reside in the emissive layer.

6. The display device claimed in claim 1, wherein the hole drift layer is doped with a P-type dopant and the electron transport layer is doped with an N-type dopant.

7. The display device claimed in claim 1, wherein the electron transport layer is doped with an N-type dopant.

8. The display device claimed in claim 7, wherein the electron transport layer is doped with elements selected from the group consisting of sulfur, phosphorus, lithium, bromine, iodine, sodium nitrogen, and a refractory metal.

9. The display device claimed in claim 1, wherein the electron transport layer is either a single or highly polycrystalline structure.

10. The display device claimed in claim 1, wherein the electron transport layer has a bandgap energy level greater than an energy level of electron-hole recombination pairs that reside in the emissive layer.

11. The display device claimed in claim 1, wherein the substrate is diamond, glass, semi-conductor, polymer, or metal.

12. The display device claimed in claim 1, wherein the display device is an OLED display.

13. The display device claimed in claim 12, wherein the emissive layer is a fluorescent organic crystalline or polymeric solid.

14. The display device claimed in claim 1, wherein the encapsulation layer is coated with material selected from the group consisting of diamond, diamond-like carbon, glass, metal, polymer, and semi-conductor.

15. The display device claimed in claim 1, wherein the encapsulation layer is either a single crystalline, polycrystalline, or diamond-like structure.

16. The display device claimed in claim 15, wherein the encapsulation layer has properties selected from the group consisting of high thermal conductivity, low specific heat, high transmittance, and a high refractive index.

17. An OLED display device with multiple low temperature diamond coatings, comprising:
a) a diamond substrate as a base upon which the OLED device is built;
b) an anode layer residing on the diamond substrate for emitting holes;
c) a hole drift layer that includes a doped diamond coating residing on the anode layer;
d) an emissive layer for emitting light and residing on the hole drift layer;
e) an electron transport layer that includes a doped diamond coating residing on the emissive layer;
f) a cathode layer, residing on the electron transport layer, for emitting electrons that will drift towards the emissive layer; and
g) a diamond coated encapsulation layer for sealing the OLED device from atmospheric moisture; wherein the multiple low temperature diamond coatings are all formed below 750° C. on the OLED device.

18. The OLED display device claimed in claim 17, wherein the diamond substrate is a transparent insulating material of either single crystalline, polycrystalline or a diamond-like carbon structure.

19. The OLED display device claimed in claim 17, wherein the diamond substrate is formed on a rigid backplane.

20. The OLED display device claimed in claim 17, wherein the diamond substrate is formed on a flexible backplane.

21. The OLED display device claimed in claim 17, wherein the multiple low temperature diamond coatings have the well-defined Raman spectral single peak at 1332 cm⁻¹ characteristic of pure or nearly pure diamond.

22. The OLED display device claimed in claim 17, wherein the multiple low temperature diamond coatings have the Raman spectral broad band in the range of 1357 to 1580 cm⁻¹ with a single peak within the range of 1357 to 1580 cm⁻¹, characteristic of diamond-like carbon.

23. The OLED display device claimed in claim 17, wherein the diamond substrate is formed on semiconductor material, a polymer, a metal, or a glass.

24. The OLED display device claimed in claim 23, wherein the diamond substrate is formed on rigid backplane.

25. The OLED display device claimed in claim 17, wherein the diamond substrate is connected to an active matrix backplane to form an active matrix display device fabricated on rigid or flexible transparent substrates.

26. The OLED display device claimed in claim 17, wherein the diamond substrate is connected to an passive matrix backplane to form a passive matrix display device fabricated on rigid or flexible transparent substrates.

27. The OLED display device claimed in claim 25, wherein the diamond substrate is connected to an optical fiber's emitting end, wherein the optical fiber is connected to the active matrix backplane to form an active matrix display device.

28. The OLED display device claimed in claim 27, wherein a plurality of optical fibers that emit colored light connect to form one or more colored pixels.

29. A method for fabricating an OLED device with multiple low temperature diamond coatings, comprising the steps of:
a) preparing a backplane for subsequent build up of the OLED device;
b) depositing a diamond substrate as a base upon the backplane;
c) depositing an anode layer on the diamond substrate for emitting holes;
d) depositing a hole transport layer that includes a doped diamond coating residing on the anode layer;
e) depositing an emissive layer residing on the hole transport layer;
f) depositing an electron transport layer upon the emissive layer;
g) depositing a cathode layer upon the electron transport layer for emitting electrons that will drift towards the light-emitting layer;
h) depositing a diamond coated encapsulation layer for sealing the OLED device from atmospheric moisture; wherein the multiple low temperature diamond coatings are all formed on the OLED device below 750° C.

30. The method claimed in claim 29, wherein the anode layer is formed of material selected from the group consisting of gold, nickel, platinum, molybdenum, indium-tin-oxide, tin oxide, zinc oxide or any combination thereof.

31. The method claimed in claim 29, wherein the anode layer is formed of thin metals or transparent films.

32. The method claimed in claim 29, wherein the anode layer is formed of high work function material that easily releases holes from the anode layer.

33. The method claimed in claim 29, wherein the hole transport layer is either a single or highly polycrystalline structure.

34. The method claimed in claim 29, wherein the hole transport layer has a bandgap energy level greater than an energy level of electron-hole recombination pairs that reside in the emissive layer.

35. The method claimed in claim 29, wherein the hole transport layer is a p-type semiconductor.

36. The method claimed in claim 35, wherein the hole transport layer is doped with elements selected from the group consisting of boron, hydrogen, palladium, or silicon.

37. The method claimed in claim 29, wherein the electron transport layer is either a single or highly polycrystalline structure.

38. The method claimed in claim 29, wherein the electron transport layer has a bandgap energy level greater than an energy level of electron-hole recombination pairs that reside in the emissive layer.

39. The method claimed in claim 29, wherein the electron transport layer is an n-type semiconductor.

40. The method claimed in claim 39, wherein the electron transport layer is doped with elements selected from the group consisting of sulfur, phosphorus, lithium, bromine, iodine, sodium nitrogen, and a refractory metal.

41. The method claimed in claim 40, wherein the refractory metal is selected from the group consisting of rhenium, tungsten, tantalum, molybdenum, niobium, and vanadium.

42. The method claimed in claim 29, wherein the cathode layer is made with elements selected from the group consisting of magnesium, magnesium silver, calcium, calcium aluminum, lithium fluoride, lithium fluoride aluminum, gold aluminum, indium tin oxide, chrome gold and copper.

43. The method claimed in claim 42, wherein the cathode layer is formed of low work function material that easily releases electrons from the cathode layer.

44. The method claimed in claim 29, wherein the encapsulation layer is either a single crystalline, polycrystalline, or diamond-like structure.

45. The method claimed in claim 44, wherein the encapsulation layer has properties selected from the group consisting of high thermal conductivity, low specific heat, high transmittance, and a high refractive index.

46. The method claimed in claim 29, wherein deposition of layers in steps b-g is conducted between 100° C. and 750° C.

47. The method claimed in claim 29, wherein the diamond substrate is a transparent insulating material of either single crystalline, polycrystalline or a diamond-like carbon structure.

48. The method claimed in claim 29, wherein the diamond substrate is formed on a rigid backplane.

49. The method claimed in claim 29, wherein the diamond substrate is formed on a flexible backplane.

50. The method claimed in claim 29, wherein the multiple low temperature diamond coatings have a well-defined Raman spectral single peak at 1332 cm⁻¹ for a pure or nearly pure diamond coating.

51. The method claimed in claim 29, wherein the multiple low temperature diamond coatings have a Raman spectral broad band in the range of 1357 to 1580 cm⁻¹ having a single peak within the range of 1357 to 1580 cm⁻¹, for a diamond-like coating.

52. A method for fabricating an OLED device with multiple low temperature diamond coatings, comprising the steps of:
a) preparing a backplane for subsequent build up of the OLED device;
b) depositing a diamond substrate as a base upon the backplane;
c) depositing an anode layer on the diamond substrate for emitting holes;
d) depositing a hole transport layer that includes a doped diamond coating residing on the anode layer;
e) depositing an emissive layer residing on the hole transport layer;
f) depositing an electron transport layer upon the emissive layer;
g) depositing a cathode layer upon the electron transport layer for emitting electrons that will drift towards the light-emitting layer;
h) depositing a diamond coated encapsulation layer for sealing the OLED device from atmospheric moisture; wherein the multiple low temperature diamond coatings are all formed on the OLED device, below 750° C., during a single continuous process.

53. A method for fabricating a display device with multiple low temperature diamond coatings, comprising the steps of:
a) preparing a backplane for the display device;
b) depositing a substrate as a base upon the backplane;
c) depositing an anode layer on the substrate for emitting holes;
d) depositing a hole transport layer that includes a doped diamond coating residing on the anode layer;
e) depositing an emissive layer residing on the hole transport layer;
f) depositing an electron transport layer upon the emissive layer;
g) depositing a cathode layer upon the electron transport layer for emitting electrons that will drift towards the light emitting layer; and
h) depositing a diamond coated encapsulation layer for sealing the OLED device from atmospheric moisture; wherein the multiple low temperature diamond coatings are all formed on the OLED device, below 750° C.

54. The method claimed in claim 53, wherein the substrate is diamond, glass, semi-conductor, polymer, or metal.

55. The method claimed in claim 53, wherein the anode layer is formed of material selected from the group consisting of gold, nickel, platinum, molybdenum, indium-tin-oxide, tin oxide, zinc oxide or any combination thereof.

56. The method claimed in claim 53, wherein the anode layer is formed of thin metals or transparent films.

57. The method claimed in claim 53, wherein the anode layer is formed of high work function material that easily releases holes from the anode layer.

58. The method claimed in claim 53, wherein the hole transport layer is either a single or highly polycrystalline structure.

59. The method claimed in claim 53, wherein the hole transport layer has a bandgap energy level greater than an energy level of electron-hole recombination pairs that reside in the emissive layer.

60. The method claimed in claim 53, wherein the hole transport layer is a p-type semiconductor.

61. The method claimed in claim 60, wherein the hole transport layer is doped with elements selected from the group consisting of boron, hydrogen, palladium, or silicon.

62. The method claimed in claim 53, wherein the electron transport layer is either a single or highly polycrystalline structure.

63. The method claimed in claim 53, wherein the electron transport layer has a bandgap energy level greater than an energy level of electron-hole recombination pairs that reside in the emissive layer.

64. The method claimed in claim 53, wherein the electron transport layer is an n-type semiconductor.

65. The method claimed in claim 64, wherein the electron transport layer is doped with elements selected from the group consisting of sulfur, phosphorus, lithium, bromine, iodine, sodium nitrogen, and a refractory metal.

66. The method claimed in claim 65, wherein the refractory metal is selected from the group consisting of rhenium, tungsten, tantalum, molybdenum, niobium, and vanadium.

67. The method claimed in claim 53, wherein the cathode layer is made with elements selected from the group consisting of magnesium, magnesium silver, calcium, calcium aluminum, lithium fluoride, lithium fluoride aluminum, gold aluminum, indium tin oxide, chrome gold and copper.

68. The method claimed in claim 67, wherein the cathode layer is formed of low work function material that easily releases electrons from the cathode layer.

69. The method claimed in claim 53, wherein the encapsulation layer is either a single crystalline, polycrystalline, or diamond-like structure.

70. The method claimed in claim 69, wherein the encapsulation layer has properties selected from the group consisting of high thermal conductivity, low specific heat, high transmittance, and a high refractive index.

71. The method claimed in claim 53, wherein deposition of layers in steps b-h is conducted between 100° C. and 750° C.

72. The method claimed in claim 54, wherein the diamond substrate is a transparent insulating material of either single crystalline, polycrystalline or a diamond-like carbon structure.

73. The method claimed in claim 54, wherein the diamond substrate is formed on a rigid backplane.

74. The method claimed in claim 54, wherein the diamond substrate is formed on a flexible backplane.

75. The method claimed in claim 53, wherein the multiple low temperature diamond coatings have a well-defined Raman spectral single peak at 1332 cm⁻¹ for a pure or nearly pure diamond coating.

76. The method claimed in claim 53, wherein the multiple low temperature diamond coatings have a Raman spectral broad band in the range of 1357 to 1580 cm⁻¹ having a single peak within the range of 1357 to 1580 cm⁻¹, for a diamond-like coating.
